(19) United States
(12) Patent Application Publication
(10) Pub. No.: US 2012/0077292 A1
(43) Pub. Date: Mar. 29, 2012

(54) METHOD OF MANUFACTURING LIGHT EMITTING DIODE PACKAGE

(75) Inventors: CHAO-HSIUNG CHANG, Hukou (TW); PI-CHIANG HU, Hukou (TW)

(73) Assignee: ADVANCED OPTOELECTRONIC TECHNOLOGY, INC., Hsinchu Hsien (TW)

(21) Appl. No.: 13/157,318

(22) Filed: Jun. 10, 2011

(30) Foreign Application Priority Data
Sep. 23, 2010 (CN) 201010288449.4

(51) Int. Cl. H01L 33/52; H01L 33/60

(52) U.S. Cl. 438/27; 438/26; 257/E33.059; 257/E33.072

(57) ABSTRACT

An exemplary method of manufacturing an LED package includes providing a base, the base having a reflecting cup with a receiving recess defined therein; an LED chip is then mounted on the base and secured in a bottom of the receiving recess; thereafter, a dispensing nozzle is used to apply an encapsulating material into the receiving recess to encapsulate the LED chip; finally, the encapsulating material is baked to form an encapsulating layer. The dispensing nozzle moves relative to the receiving recess during the application of the encapsulating material. A depth of the receiving recess is varied. Parameters of the application of the encapsulating material into the receiving recess by the dispensing nozzle vary in response to a change of the depth of the receiving recess.

### BACKGROUND

1. Technical Field

The present disclosure relates generally to light emitting devices, and more particularly to a method of manufacturing a light emitting diode (LED) package.

2. Description of Related Art

LEDs are solid state light emitting devices formed of semiconductors, which are more stable and reliable than other conventional light sources such as incandescent bulbs. Thus, LEDs are being widely used in various fields such as numeral/character displaying elements, signal lights, light sources for lighting and display devices. When in use, providing LEDs in packages can provide protection, color selection, focusing and the like for light emitted by the LEDs. Generally, a process of packaging an LED chip includes bonding, encapsulating, baking, cutting etc.

In a typical packaging process, an encapsulating material such as a viscous, jelly-like material is brought to fill into a reflecting cup in which the LED chip is mounted to cover the LED chip by a technique of insert molding. The encapsulating material has a certain degree of viscosity. During the insert molding of the encapsulating material, the encapsulating material is prone to spill over the reflecting cup, and unevenly cover the LED chip. The above mentioned factors not only affect the lighting efficiency of the LED package, but also destroy the aesthetics of the LED package.

What is needed therefore is a method of manufacturing an LED package which can overcome the above mentioned limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIGS. 1-4 are schematic views showing different steps of a manufacturing method for forming an LED package in accordance with an embodiment of the present disclosure.

FIG. 5 is a graph illustrating variations of different parameters of application of encapsulating material corresponding to different positions of a dispensing nozzle relative to a receiving recess of the LED package.

FIG. 6 illustrates an encapsulating process of a manufacturing method of an LED package in accordance with an alternative embodiment of the present disclosure.

### DETAILED DESCRIPTION

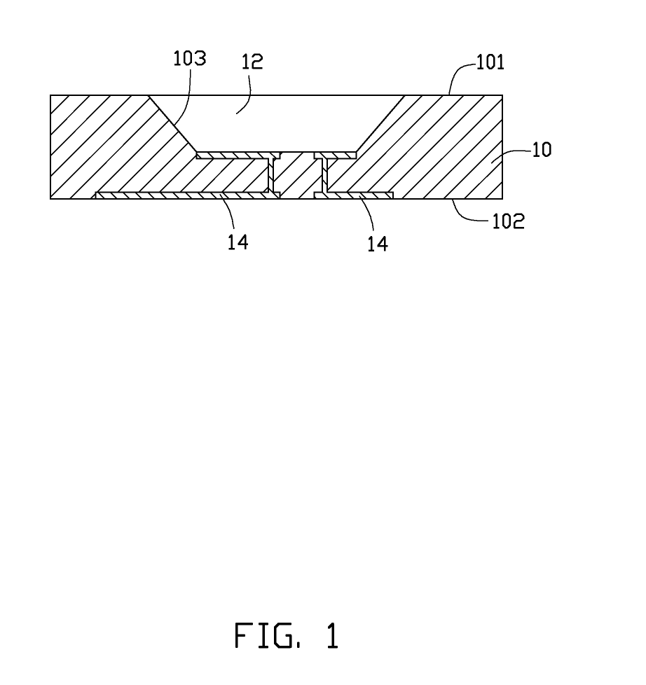

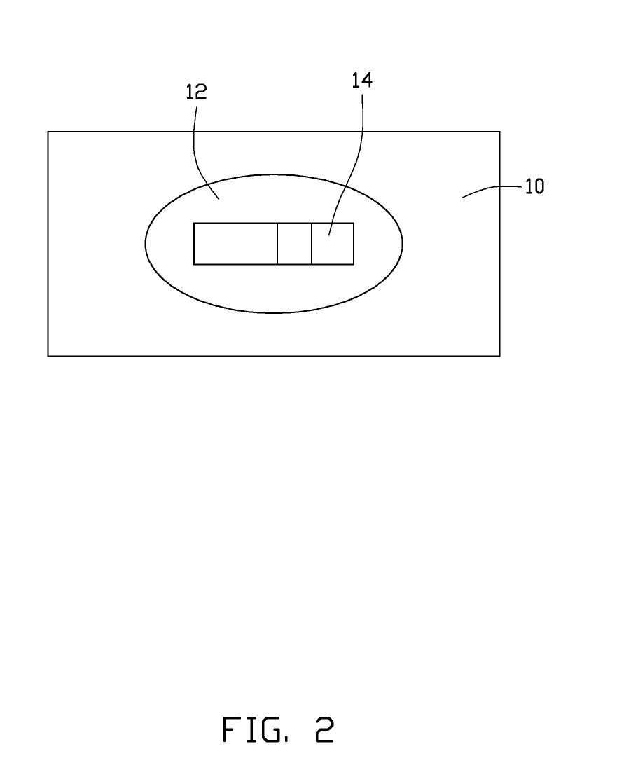

A method of manufacturing an LED package provided by the present disclosure substantially comprises bonding, encapsulating and baking. Firstly, a base 10 is provided. FIG. 1 is a cross sectional view of the base 10, and FIG. 2 is a top view of the base 10. The base 10 comprises a first surface 101 and an opposite second surface 102. The first surface 101 may be a top surface, and the second surface 102 may be a bottom surface. A receiving recess 12 is defined in the first surface 101. An inner surface 103 of the base 10 surrounding the receiving recess 12 functions as a reflecting cup. Referring to FIG. 2, the receiving recess 12 has a substantially elliptic top opening. A bottom of the receiving recess 12 has a rectangular shape, and is substantially parallel to the first surface 101. A width of the receiving recess 12 increases gradually along a bottom-to-top direction, meanwhile a depth of the receiving recess 12 increases along a periphery-to-center direction. The depth of the receiving recess 12 is constant and maximum at a central portion of the receiving recess 12 which is located over the deepest bottom of the receiving recess 12. It is understood that the receiving recess 12 can be another shape such as that like a conical frustum or a pyramidal frustum in an alternative embodiment.

Electrical structures 14 are formed on the second surface 102 of the base 10. The electrical structures 14 extend through the base 10 and are exposed on the bottom of the receiving recess 12. In this embodiment, two separate grooves are defined in the second surface 102 respectively receiving the electrical structures 14 therein. Bottoms of the electrical structures 14 are coplanar with the second surface 102 of the base 10.

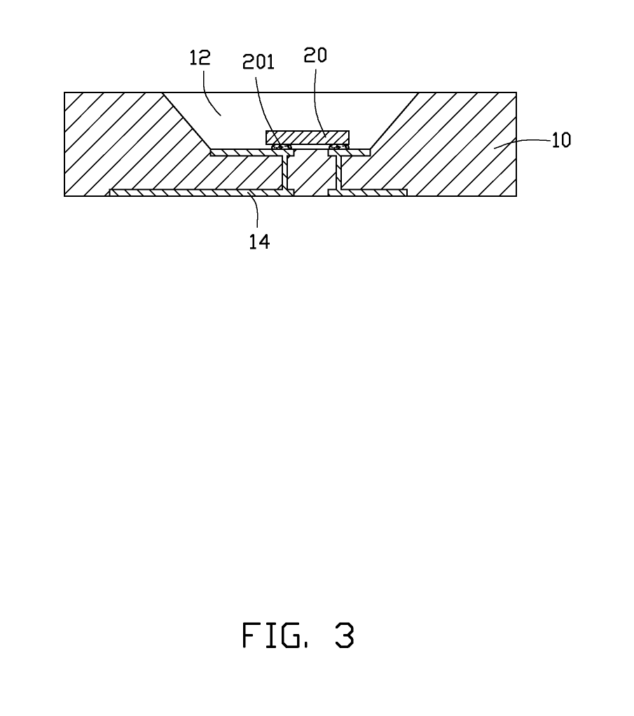

Referring to FIG. 3, an LED chip 20 is provided and bonded at the bottom of the receiving recess 12. The LED chip 20 is electrically connected to the electrical structures 14 by conducting glue 201 using a flip-chip method. It is noted that the LED chip 20 can be electrically connected to the electrical structures 14 by metal wires in alternative embodiments.

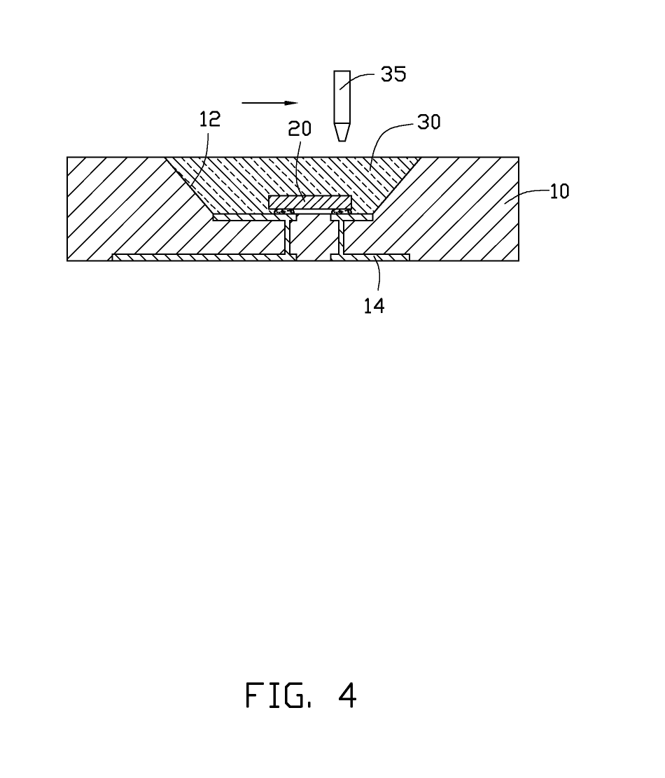

FIG. 4 shows an encapsulating process of the manufacturing method. A viscous encapsulating material 30 is contained in a container (not shown) and applied to the receiving recess 12 through a dispensing nozzle 35. The encapsulating material 30 is received in the receiving recess 12 and covers the LED chip 20. During the application of the encapsulating material 30 into the receiving recess 12, the dispensing nozzle 35 moves relative to the receiving recess 12 in a horizontal plane. Since the depth of the receiving recess 12 varies in different positions, the volume of the encapsulating material 30 provided for different positions of the receiving recess 12 varies accordingly. By moving the dispensing nozzle 35 relative to the receiving recess 12, the volume of the encapsulating material 30 retained at different positions of the receiving recess 12 can be well controlled. Thus, the spilling of the encapsulating material 30 out of the receiving recess 12 can be avoided. The dispensing nozzle 35 can move from a side of the receiving recess 12 to an opposite side along the direction shown by the arrow in FIG. 4. That is, the dispensing nozzle 35 moves along a direction of the major axis of the opening of the receiving recess 12. The moving path of the dispensing nozzle 35 is a straight line in this embodiment. The moving paths of the dispensing nozzle 35 can be others such as radial lines from a center of the opening to the periphery of the opening, or spiral lines in alternative embodiments. The encapsulating material 30 is then filled in the reflecting cup and is level with the first surface 101 of the base 10, which is coincidental with a top of the reflecting cup. Such an encapsulating method is more convenient compared with the molding method in which a mold is needed.

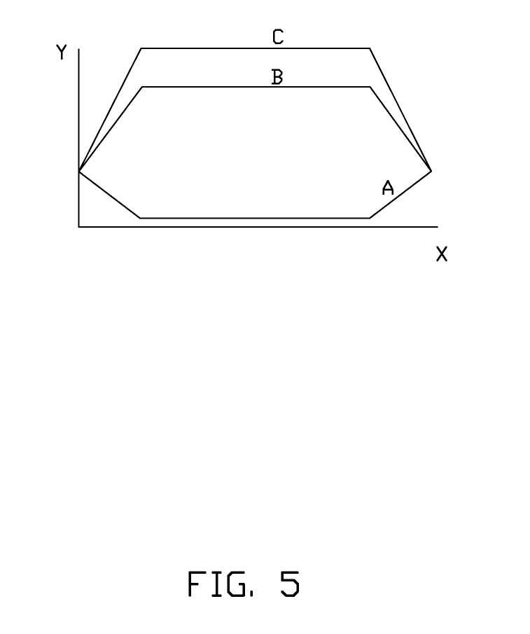

Further, a plurality of parameters of the dispensing nozzle 35 such as the moving speed, the dispensing speed and the dispensing pressure can vary according to different positions of the dispensing nozzle 35 relative to the receiving recess 12. Referring to FIG. 5, the horizontal axis X represents the moving path of the dispensing nozzle 35 shown in FIG. 4, and the vertical axis Y represents the depth of the receiving recess 12. Curve A represents change of the moving speed of the dispensing nozzle 35. Curve B represents change of the dispensing speed of the encapsulating material 30 from the dispensing nozzle 35. Curve C represents change of the dispensing pressure of the encapsulating material 30 from the dispensing nozzle 35.

The moving speed of the dispensing nozzle 35 increases as decrease of the depth of the receiving recess 12. When the dispensing nozzle 35 is located over the central portion of the receiving recess 12, the moving speed of the dispensing nozzle 35 is remained at a minimum value. The dispensing speed of the encapsulating material 30 from the dispensing nozzle 35 increases as increase of the depth of the receiving recess 12. When the dispensing nozzle 35 is located over the central portion of the receiving recess 12, the dispensing speed of the encapsulating material 30 from the dispensing nozzle 35 is remained at a maximum value. The dispensing pressure of the encapsulating material 30 from the dispensing nozzle 35 increases as increase of the depth of the receiving recess 12. When the dispensing nozzle 35 is located over the central portion of the receiving recess 12, the dispensing pressure of the encapsulating material 30 from the dispensing nozzle 35 is remained at a maximum value. The variations of the parameters of the dispensing nozzle 35 during the encapsulation can be changed when the configuration of the receiving recess 12 changes.

Furthermore, during the encapsulation, the pattern of the variations of the parameters of the dispensing nozzle 35 shown in FIG. 5 can be changed while to obtain the similar encapsulating characteristics obtainable by FIG. 5. For example, the dispensing speed of the encapsulating material 30 and the dispensing pressure of the encapsulating material 30 from the dispensing nozzle 35 remain unchanged, while the moving speed of the dispensing nozzle 35 varies along a curve which is different from the curve A in FIG. 5.

Alternatively, during the encapsulation, two of the parameters of the dispensing nozzle 35 can vary, while the other parameter remains unchanged. For example, the dispensing speed of the encapsulating material 30 from the dispensing nozzle 35 remains unchanged, while the moving speed of the dispensing nozzle 35 and the dispensing pressure of the encapsulating material 30 from the dispensing nozzle 35 vary.

After the filling of the encapsulating material 30 in the receiving recess 12, the encapsulating material 30 is baked to form a solid encapsulating layer, whereby the packaging is substantially completed.

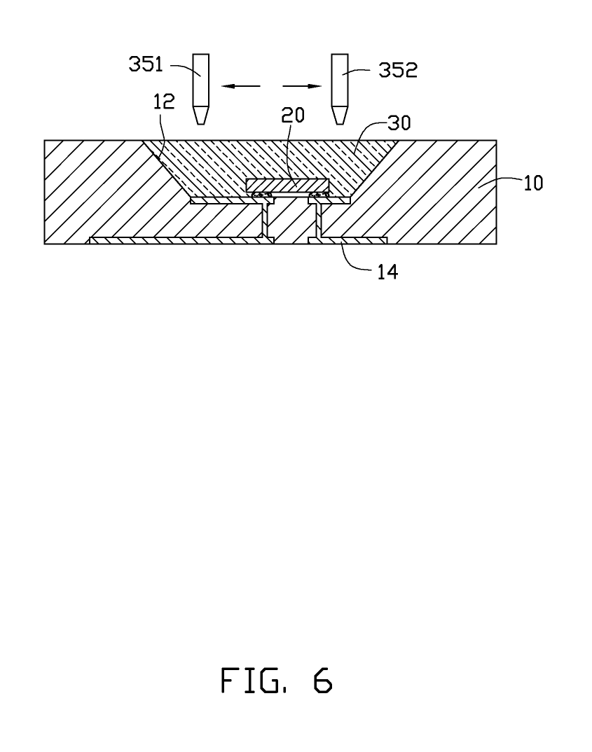

FIG. 6 shows an encapsulating process of a manufacturing method of an LED package in accordance with an alternative embodiment of the present disclosure. The difference between the present embodiment and the previous embodiment is that two dispensing nozzles 351, 352 are used during the encapsulation in accordance with the present embodiment. The dispensing nozzles 351, 352 move from the central portion of the receiving recess 12 to the outer periphery of the receiving recess 12 along the direction shown by the arrows in FIG. 6 respectively. The moving paths of the dispensing nozzles 351, 352 can alter as described in the previous embodiment. The parameters of the dispensing nozzles 351, 352 such as the moving speed thereof, the dispensing speed of the encapsulating material 30 from the dispensing nozzles 351, 352, and the dispensing pressure of the encapsulating material 30 from the dispensing nozzles 351, 352 can vary in a manner similar to the rules described in the previous embodiment.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A method of manufacturing a light emitting diode (LED) package comprising:
providing a base, the base having a reflecting cup with a receiving recess defined therein;
providing an LED chip and mounting the LED chip in a bottom of the receiving recess;
using a dispensing nozzle to apply an encapsulating material into the receiving recess to encapsulate the LED chip, the dispensing nozzle moving relative to the receiving recess during the application of the encapsulating material into the receiving recess; and
baking the encapsulating material to form an encapsulating layer.

2. The method of claim 1, wherein the dispensing nozzle moves from one side to an opposite side of the receiving recess during the application of the encapsulating material into the receiving recess.

3. The method of claim 1, wherein a depth of the receiving recess increases inward from an outer periphery thereof, and the depth of the receiving recess at a central portion thereof remains unchanged and has a maximum value.

4. The method of claim 3, wherein a moving speed of the dispensing nozzle increases as the depth of the receiving recess decreases.

5. The method of claim 4, wherein when the dispensing nozzle is located at the central portion of the receiving recess, the moving speed of the dispensing nozzle is remained at a minimum value.

6. The method of claim 3, wherein a speed of dispensation of the encapsulating material from the dispensing nozzle increases as the depth of the receiving recess increases.

7. The method of claim 6, wherein when the dispensing nozzle is located at the central portion of the receiving recess, the speed of dispensation of the encapsulating material from the dispensing nozzle is remained at a maximum value.

8. The method of claim 3, wherein a pressure of dispensation of the encapsulating material from the dispensing nozzle increases as the depth of the receiving recess increases.

9. The method of claim 8, wherein when the dispensing nozzle is located at the central portion of the receiving recess, the pressure of dispensation of the encapsulating material from the dispensing nozzle is remained at a maximum value.

10. The method of claim 3, wherein the encapsulating layer is level with a top of the reflecting cup.

11. The method of claim 1, wherein an additional dispensing nozzle is used to cooperate with the dispensing nozzle to apply the encapsulating material into the receiving recess.

12. The method of claim 11, wherein the dispensing nozzle and the additional dispensing nozzle move from a central portion of the receiving recess to an outer periphery of the receiving recess respectively.

13. A method of manufacturing an LED package comprising:
providing a base, the base defining a receiving recess with an LED chip received therein;
using at least one dispensing nozzle to apply an encapsulating material into the receiving recess to encapsulate the LED chip, the at least one dispensing nozzle moving at a horizontal plane relative to the receiving recess during the application of the encapsulating material into the receiving recess; and
baking the encapsulating material to form an encapsulating layer.

14. The method of claim 13, wherein during the application of the encapsulating material into the receiving recess, the at least one dispensing nozzle moves radially from a center portion of the receiving recess to an outer periphery of the receiving recess, straightly from one side of the receiving recess to an opposite side of the receiving recess, or spirally.

15. The method of claim 13, wherein at least one of moving speed of the at least one dispensing nozzle, dispensing speed of the encapsulating material from the at least one dispensing nozzle and dispensing pressure of the encapsulating material from the at least one dispensing nozzle varies in response to a variation of depth of the receiving recess, and the moving speed decreases, the dispensing speed and the dispensing pressure increase as the depth of the receiving recess increases.
